(19) United States
(12) Patent Application Publication
(10) Pub. No.: US 2024/0022247 A1
(43) Pub. Date: Jan. 18, 2024

(54) QUANTUM CIRCUIT FOR PAIRWISE TESTING

(71) Applicant: International Business Machines Corporation, Armonk, NY (US)

(72) Inventors: Shashanka Ubaru, Ossining, NY (US); Ismail Yunus Akhalwaya, Emmarentia (ZA); Mark S. Squillante, Greenwich, CT (US); Kenneth Lee Clarkson, Madison, NJ (US); Vasileios Kalantzis, White Plains, NY (US); Lior Horesh, North Salem, NY (US)

(21) Appl. No.: 17/863,484

(22) Filed: Jul. 13, 2022

(51) Int. Cl. H03K 17/92; G06N 10/40; G06N 10/60

(52) U.S. Cl. CPC H03K 17/92; G06N 10/40; G06N 10/60

(57) ABSTRACT

Systems and methods for performing pairwise checking of data points in a dataset are described. An apparatus or computing device can include a controller, quantum hardware, and an interface. The controller can be configured to generate a command signal. The quantum hardware can include a plurality of qubits. The interface can be connected to the controller and the quantum hardware. The interface can be configured to control the quantum hardware based on the command signal received from the controller to perform pairwise checking for every pair of data points in a dataset to identify a property relating to the data points. The data points can be represented by the plurality of qubits.

### STATEMENT REGARDING FEDERALLY SPONSORED RESEARCH OR DEVELOPMENT

This invention was made with Government support under FA8750-C-18-0098 awarded by U.S. Air Force Research Lab. The Government has certain rights to this invention.

### STATEMENT REGARDING PRIOR DISCLOSURES BY THE INVENTOR OR A JOINT INVENTOR

The following disclosure(s) are submitted under 35 U.S.C. 102(b)(1)(A): Quantum Computing Algorithms for Decision Making under Uncertainty, Lior Horesh, Ken Clarkson, Vasileios Kalantzis, Mark Squillante, Shashanka Ubaru, Amir Abboud, July 2021; Quantum Topological Data Analysis with Linear Depth and Exponential Speedup, Shashanka Ubaru, Ismail Yunus Akhalwaya, Mark S. Squillante, Kenneth L. Clarkson, Lior Horesh, arXiv:2108.02811v1, Aug. 5, 2021.

### BACKGROUND

The present disclosure relates in general to systems and methods for quantum computing. In particular, the present disclosure provides a quantum circuit that can be implemented by a quantum computer to perform complete pairwise testing.

Classical computers use transistors to encode information in binary data, such as bits, where each bit can represent a value of 1 or 0. These 1s and 0s act as on/off switches that drive classical computer functions. If there are n bits of data, then there are 2ⁿ possible classical states, and one state is represented at a time.

Quantum computers uses quantum processors that operate on data represented by quantum bits, also known as qubits. One qubit can represent the classical binary states ‘0’, ‘1’, and also additional states that are superposition of states of ‘0’ and ‘1’. Due to the ability to represent superpositions of ‘0’ and ‘1’, a qubit can represent both ‘0’ and ‘1’ states at the same time. For example, if there are n bits of data, then 2ⁿ quantum states can be represented at the same time. Further, qubits in a superposition can be correlated with each other, referred to as entanglement, where the state of one qubit (whether it is a 1 or a 0 or both) can depend on the state of another qubit, and more information can be encoded within the two entangled qubits. Based on superposition and entanglement principles, qubits can enable quantum computers to perform functions that may be relatively complex and time consuming for classical computers.

### SUMMARY

In one embodiment, an apparatus for pairwise checking is generally described. The apparatus can include a controller configured to generate a command signal. The apparatus can further include quantum hardware including a plurality of qubits. The apparatus can further include an interface connected to the controller and the quantum hardware. The interface can be configured to control the quantum hardware based on the command signal received from the controller to perform pairwise checking for every pair of data points in a dataset to identify a property relating to the data points. The data points can be represented by the plurality of qubits.

In another embodiment, a system for pairwise checking is generally described. The system can include a first computing device configured to process data encoded in binary data. The system can further include a second computing device configured to be in communication with the first computing device. The second computing device can be configured to process data encoded in qubits. The second computing device can include a controller configured to at least receive an instruction from the first computing device. The controller can be configured to generate a command signal based on the instruction. The second computing device can further include quantum hardware including a plurality of qubits. The second computing device can further include an interface connected to the controller and the quantum hardware. The interface can be configured to control the quantum hardware based on the command signal received from the controller to perform pairwise checking for every pair of data points in a dataset to identify a property relating to the data points. The data points can be represented by the plurality of qubits.

In another embodiment, a method for operating a quantum system to perform pairwise checking is generally described. The method can include receiving, by a controller of a quantum system, an instruction. The method can further include, generating, by the controller the quantum system, a command signal based on the instruction. The method can further include converting, by an interface of the quantum system, the command signal into a quantum operation. The method can further include, based on the quantum operation, controlling, by the interface of the quantum system, quantum hardware of the quantum system to perform pairwise checking for every pair of data points in a dataset to identify a property relating to the data points. The data points can be represented by the plurality of qubits.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a block diagram of an example system for a quantum circuit for pairwise testing in one embodiment.

FIG. 2 is a diagram illustrating a cyclic shift technique to select pairs of vertices for different iterations of pairwise testing in one embodiment.

FIG. 3 is a diagram illustrating a plurality of simplices that may be in a simplicial complex in one embodiment.

FIG. 4 is a diagram illustrating an example quantum circuit that can be implemented as a quantum circuit for pairwise testing in one embodiment.

FIG. 5 is a diagram illustrating an example result of an implementation of the quantum circuit shown in FIG. 4 in one embodiment.

FIG. 6A is a diagram illustrating a first portion of an example quantum circuit that can be implemented as a quantum circuit for pairwise testing in one embodiment.

FIG. 6B is a diagram illustrating a second portion of the example quantum circuit in FIG. 6A that can be implemented as a quantum circuit for pairwise testing in one embodiment.

FIG. 7 is a diagram illustrating another example quantum circuit that can be implemented as a quantum circuit for pairwise testing in one embodiment.

FIG. 8A is a flowchart of an example process that may implement a quantum circuit for pairwise testing according to an embodiment of the disclosure.

FIG. 8B is another flowchart of an example process that may implement a quantum circuit for pairwise testing according to an embodiment of the disclosure.

FIG. 9 illustrates a schematic of an example computer or processing system that may implement a quantum circuit for pairwise testing in one embodiment of the present disclosure.

FIG. 10 illustrates a schematic of an example quantum computing system that may implement a quantum circuit for pairwise testing in one embodiment of the present disclosure.

FIG. 11 illustrates a block diagram of an example system that can facilitate execution of a quantum algorithm in one embodiment of the present disclosure.

FIG. 12 depicts a cloud computing environment according to an embodiment of the present invention.

FIG. 13 depicts abstraction model layers according to an embodiment of the present invention.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following descriptions, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

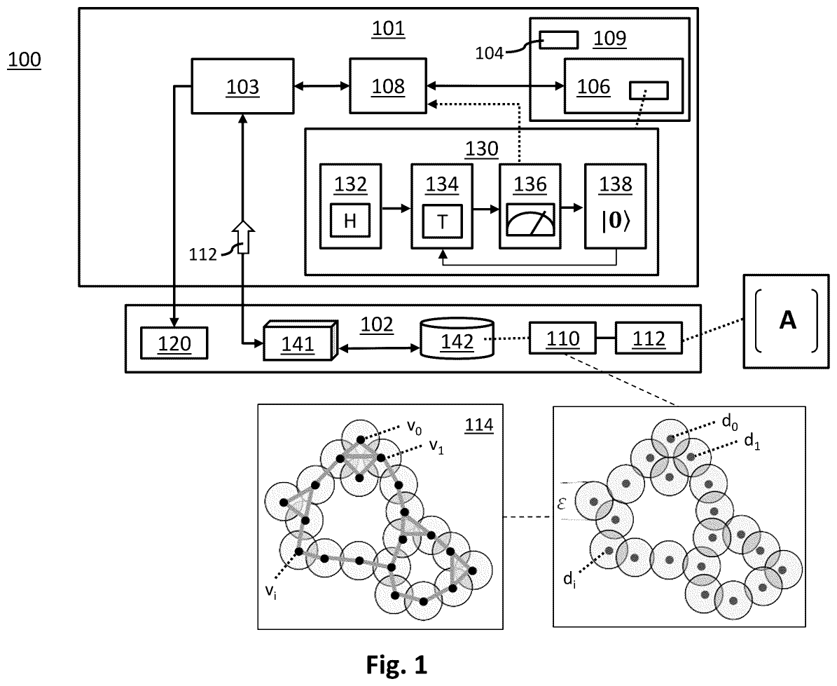

FIG. 1 is a block diagram of an example system 100 for a quantum circuit for pairwise testing in one embodiment. System 100 can be a hybrid computing system including a combination of one or more quantum computers, quantum systems, and/or classical computers. In an example shown in FIG. 1, system 100 can include a quantum system 101 and a classical computer 102. In one embodiment, quantum system 101 and classical computer 102 can be configured to be in communication via one or more of wired connections and wireless connections (e.g., a wireless network). Quantum system 101 can include a quantum chipset that includes various hardware components for processing data encoded in qubits. The quantum chipset can be a quantum computing core surrounded by an infrastructure to shield the quantum chipset from sources of electromagnetic noise, mechanical vibration, heat, and other sources of noise, which tend to degrade performance. Classical computer 102 can be electronically integrated, via any suitable wired and/or wireless electronic connection, with quantum system 101.

In the example shown in FIG. 1, quantum system 101 can be any suitable set of components capable of performing quantum operations on a physical system. A quantum operation can be, for example, a quantum gate operation that manipulate qubits to interact with one another in accordance with the quantum gate operation. In the example embodiment depicted in FIG. 1, quantum system 101 can include a controller 103, an interface 108, and quantum hardware 109. In some embodiments, all or part of each of controller 103, interface 108, and quantum hardware 109 can be located in a cryogenic environment to aid in the performance of the quantum operations. Quantum hardware 109 may be any hardware capable of using quantum states to process information. Such hardware may include a plurality of qubits 104, and mechanisms to couple/entangle qubits 104, in order to process information using said quantum states. Qubits 104 may include, but are not limited to, charge qubits, flux qubits, phase qubits, spin qubits, and trapped ion qubits. Quantum hardware 109 can include a set of quantum gates 130, where quantum gates 130 can be configured to perform quantum logic operations on qubits 104. Quantum gates 130 can include one or more single-qubit gates, two-qubit gates, and/or other multi-qubit gates.

Controller 103 can be any combination of digital computing devices capable of performing a quantum computation, such as executing a quantum circuit 106, in combination with interface 108. Such digital computing devices may include digital processors and memory for storing and executing quantum commands using interface 108. Additionally, such digital computing devices may include devices having communication protocols for receiving such commands and sending results of the performed quantum computations to classical computer 102. Additionally, the digital computing devices may include communications interfaces with interface 108. In one embodiment, controller 103 can be configured to receive classical instructions (e.g., from classical computer 102) and convert the classical instructions into commands (e.g., command signals) for interface 108. Command signals being provided by controller 103 to interface 108 can be, for example, digital signals indicating which quantum gates among quantum gates 106 needs to be applied to qubits 104 to perform a specific function (e.g., pairwise checking described herein). Interface 108 can be configured to convert these digital signals into analog signals (e.g., analog pulses such as microwave pulses) that can be used for applying quantum gates on qubits 104 to manipulate interactions between qubits 104.

Interface 108 can be a classical-quantum interface including a combination of devices capable of receiving commands from controller 103 and converting the commands into quantum operations for implementing quantum hardware 109. In one embodiment, interface 108 can convert the commands from controller 103 into drive signals that can drive or manipulate qubits 104, and/or apply quantum gates on qubits 104. Additionally, interface 108 can be configured to convert signals received from quantum hardware 109 into digital signals capable of processing and transmitting by controller 103 (e.g., to classical computer 102). Devices included in interface 108 can include, but are not limited to, digital-to-analog converters, analog-to-digital converters, waveform generators, attenuators, amplifiers, optical fibers, lasers, and filters. Interface 108 can further include circuit components configured to measure a basis of the plurality of qubits following the implementation of quantum gates 130, where the measurement will yield a classical bit result. For example, a basis |0 [symbol] corresponds to classical bit zero, and a basis of |1 [symbol] corresponds to classical bit one. Each measurement performed by interface 108 can be read out to a device, such as classical computer 102, connected to quantum system 101. A plurality of measurement results provided by interface 108 can result in a probabilistic outcome.

Classical computer 102 can include hardware components such as processors and storage devices (e.g., including memory devices and classical registers) for processing data encoded in classical bits. In one embodiment, classical computer 102 can be configured to control quantum system 101 by providing various control signals, commands, and data encoded in classical bits to quantum system 101. Further, quantum states measured by quantum system 101 can be read by classical computer 102 and classical computer 102 can store the measured quantum states as classical bits in classical registers. In one embodiment of an implementation, classical computer 102 can be any suitable combination of computer-executable hardware and/or computer-executable software capable of executing a preparation module 141 to perform quantum computations with data stored in data store 142 as part of building and implementing a machine learning protocol. Data store 142 may be a repository for data to be analyzed using a quantum computing algorithm, as well as the results of such analysis. Preparation module 141 may be a program or module capable of preparing classical data from data store 142 to be analyzed as part of the implementation of a quantum circuit 106. Preparation module 141 may be instantiated as part of a larger algorithm, such as a function call of an application programming interface (API) or by parsing a hybrid classical-quantum computation into aspects for quantum and classical calculation. As described in more detail below, preparation module 141 may generate instructions for creating a quantum circuit 106 using quantum gates 130. In an embodiment, such instructions may be stored by controller 103, and may instantiate the execution of the components of interface 108 so that the quantum operations of the quantum gates 130 may be performed on quantum hardware 109.

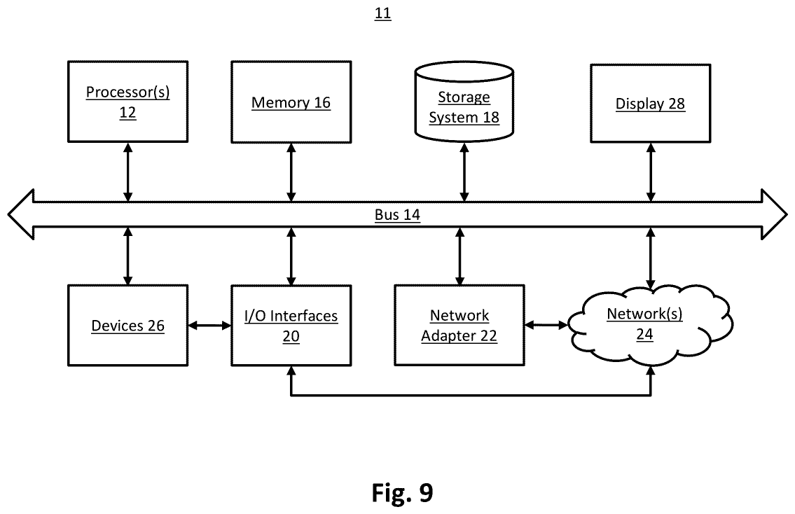

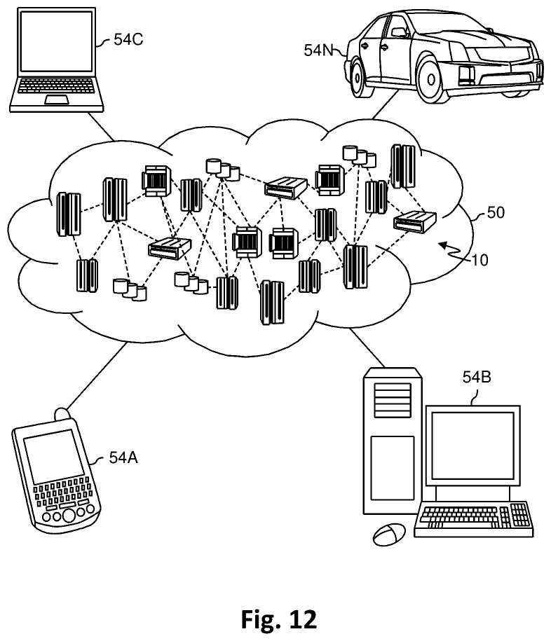

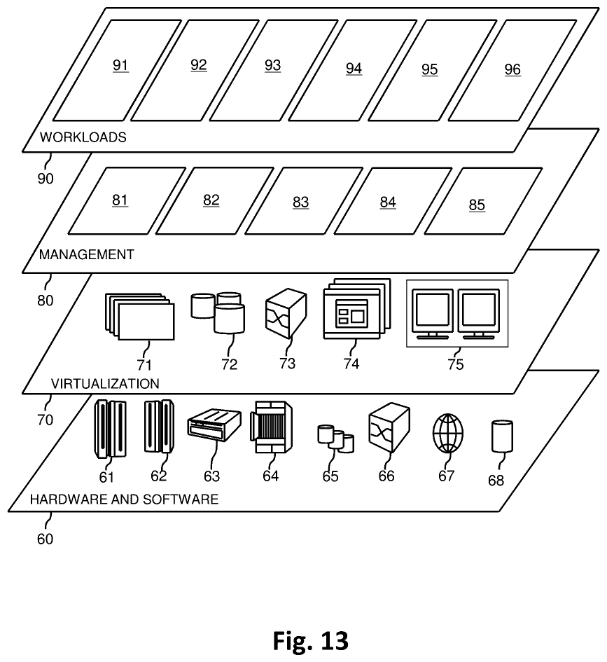

Components of classical computer 102 are described in more detail below with reference to FIG. 9. In an example system, classical computer 102 can be a laptop computer, a desktop computer, a vehicle-integrated computer, a smart mobile device, a tablet device, and/or any other suitable classical computing device. Additionally or alternatively, classical computer 102 may also operate as part of a cloud computing service model, such as Software as a Service (SaaS), Platform as a Service (PaaS), or Infrastructure as a Service (IaaS). Classical computer 102 may also be located in a cloud computing deployment model, such as a private cloud, community cloud, public cloud, or hybrid cloud. Aspects of this embodiment are described in more detail below with reference to FIG. 12 and FIG. 13.

System 100 can be implemented to perform pairwise checking of a plurality of data points in a dataset to identify one or more properties related to the plurality of data points. The pairwise checking performed by system 100 can be implemented for various applications that needs to identify specific properties that can be defined by relationship between pairs of data points. In one embodiment, system 100 can be implemented for Topological Data Analysis (TDA). Quantum computing offers the potential of exponential speedups for certain classical computations. In an aspect, quantum machine learning (QML) algorithms have been proposed as candidates for such exponential improvements. One type of data analysis that may benefit from quantum computing is Topological Data Analysis (TDA). In an aspect, TDA can consume massive datasets and reduce them to a handful of global and interpretable signature numbers, laden with predictive and analytical value.

In an aspect, given a set of data-points embedded in some ambient space, a simplicial complex can be derived from the set of data-points. A k-simplex is a collection of k+1 vertices forming a simple polytope of dimension k. For example, 0-simplices are single points (zero-dimensional), 1-simplices are line segments (one-dimensional), 2-simplices are triangles (two-dimensional), and so on. A simplicial complex is a collection of a plurality of k-simplices (of any order), and higher order simplices (e.g., higher k) can include lower order simplices. For example, a triangle simplex includes three line or edge simplices that form the triangle simplex, and also includes the three vertices (e.g., 0-simplices) connected by the three edge simplices.

Simplices in a simplicial complex Γ can be constructed as a mixed state (e.g., superposition quantum state) in quantum computing. The mixed state simplices can be projected onto the kernel of a combinatorial Laplacian Δₖ corresponding to k-simplices of simplicial complex Γ denoted as Δₖ, in order to estimate the dimension of the kernel. The estimation of the kernel dimension allows the determination of the Betti numbers, because a k-th Betti number is a kernel dimension of the combinatorial Laplacian Δₖ corresponding to k-simplices of simplicial complex F.

A combinatorial Laplacian Δ corresponding to all simplices of simplicial complex Γ can be used for determining the combinatorial Laplacian Δₖ corresponding to k-simplices. The combinatorial Laplacian Δ corresponding to all simplices of simplicial complex Γ is denoted as:

Δ=P_{Γ}BP_{Γ}BP_{Γ}

where P_{Γ} is the projector that projects the boundary operator (or boundary map) B onto all simplices present in simplicial complex Γ. The boundary operator B can create a mapping of orders of simplices (e.g., simplices of all orders) in a given simplicial complex. That is, the boundary operator can map the vector space of k-simplices into the vector space of k−1 simplices. Projector P_{Γ} is projected on a boundary operator B multiple times (e.g., three times) because boundary operator B includes a boundary conjugate that is restricted to the simplices in the simplicial complex Γ. In an example, if P_{Γ}=I, then Δ=B²=nI, and the kernel will be empty and will not include holes. The projector P_{Γ} can be used for determining the combinatorial Laplacian Δ corresponding to all simplices that are present in simplicial complex Γ. The combinatorial Laplacian Δₖ corresponding to k-simplices can be used for determining the Betti numbers of simplicial complex Γ, and the determination of Δₖ is based on Δ. If the boundary map B is known, determination of the projector P_{Γ} can lead to the determination of combinatorial Laplacian Δ, then the combinatorial Laplacian Δₖ can be determined, leading to determination of the Betti numbers of simplicial complex Γ.

In one embodiment, data store 142 may include a dataset 110, where a simplicial complex 114 can represent a topology of a plurality of data points among dataset 110 (e.g., in a database) and relationships between the plurality of data points. In an aspect, a vertex in simplicial complex 114 can represent a data point in dataset 110, and an edge or a line connecting two vertices can represent a relationship between the two vertices or data points, where the relationship can be one or more of a dependency, a shared attribute, and/or other types of relationships. Formation of simplicial complex 114 can be based on a determination of whether each pair of data points in dataset 110 are ε-close, or within a distance of ε from one another. If two data points are ε-close, then an edge can connect the two data points to form one or more simplices of simplicial complex 114. In the example shown in FIG. 1, data points d₀ and d₁ can form an ε-close pair, hence they are connected by an edge as shown in simplicial complex 114. However, data points d₀ and dᵢ are not ε-close, hence they are not connected by any edge in simplicial complex 114. In general, a k-simplex is added to simplicial complex 114 for every subset of k+1 data points that are pairwise connected (e.g., ε-close). As the value of ε varies, different data points may be connected to form different simplices, hence forming different simplicial complex.

Dataset 110 can include n data points ranging from d₀, . . . dₙ, and simplicial complex 114 can include n vertices, ranging from v₀, . . . , vₙ, representing the n data points in dataset 110. If dataset 110 has n data points, then a maximum possible number of simplices present in simplicial complex 114 is 2ⁿ. For example, if all

$$( \begin{matrix}n \\ 2\end{matrix} )$$

pairs or vertices or simplicial complex 114 are connected with one another, then simplicial complex 114 includes 2ⁿ simplices. Note that multiple simplices having the same dimension are considered as different simplices. For example, if simplicial complex 114 has n vertices, then there are n 0-simplices (e.g., single point, zero dimension simplices) in simplicial complex 114. If there are pairs of vertices that are disconnected from one another among simplicial complex 114, then the number of simplices in simplicial complex 114 will be less than 2ⁿ.

Classical computer 102 can be configured to generate an adjacency graph 112 based on dataset 110, where adjacency graph 112 can be a Vietoris-Rips 1-skeleton encoding pairwise distances of all data points in dataset 110. In one embodiment, adjacency graph 112 can be a matrix (e.g., a square matrix) and elements among the matrix can represent whether two data points are within a distance E from one another (e.g., being ε-close). To generate adjacency graph 112, classical computer 102 can encode pairwise distances between data points of dataset 110 as E-close pairs (e.g., encoding a zero when the data points are not ε-close, and encoding a one when the data points are ε-close). Adjacency graph 112 can show whether pairs of data points are E-close to one another—but may not indicate a number of simplices (and/or which simplices) that are formed in simplicial complex 114 based on the ε-close pairs.

System 100 can be implemented to construct the projector P_{Γ} that can project all simplices that can be formed by dataset 110 to construct simplicial complex 114 based on a value of ε. In one embodiment, the projector P_{Γ} can be a quantum circuit including one or more quantum gates. Classical computer 102 can send adjacency graph 112 to quantum system 101. Quantum system 101 can perform pairwise checking, or pairwise testing, on every pair of data points in dataset 110, where a result of the pairwise checking can be used for constructing projector P r. In one embodiment, classical computer 102 can determine the quantum gates (e.g., among quantum gates 130) that can be used for constructing projector P_{Γ}. Projector P_{Γ} can project a number of simplices that are present in simplicial complex 114. The pairwise testing performed by quantum system 101 can include checking every pair of data points (e.g.,

$$( \begin{matrix}n \\ 2\end{matrix} )$$

pairs) among dataset 110 to identify a property of dataset 110. Properties that can be identified include at least one of, for example, which pairs of data points are ε-close data points, whether the data points are close to each other with respect to certain metrics, whether they belong to same group or class, and/or other properties. Pairs of data points in dataset1 110 that are ε-close data points can form one or more simplices in simplicial complex 114. For example, if two data points are ε-close, then an edge can be added to connect the two data points, and the two connected data points can form a 1-simplex and/or a higher order simplex (e.g., 2-simplex or higher order) in simplicial complex 114. If two data points are not ε-close, then there will be no edge between the two data points and simplices including these two disconnected data points can be considered as absent from simplicial complex 114, and the absent simplices will not be projected by projector P_{Γ} to form simplicial complex 114.

In one embodiment, quantum system 101 can be provided with adjacency graph 112 from classical computer 102. Quantum system 101 can perform a pairwise checking on all

$$( \begin{matrix}n \\ 2\end{matrix} )$$

pairs of data points in dataset 110 to project all simplices that can be formed by ε-close pairs of data points among dataset 110. In another embodiment, quantum system 101 can be provided with adjacency graph 112 from classical computer 102, and a matrix representing vertices that form a set of projected k-simplices (e.g., P k) that can be generated by quantum system 101. The set of projected k-simplices can be simplices of a specific order k. For example, if k=2, then the matrix can represent vertices among simplicial complex that form 2-simplices. Quantum system 101 can perform the pairwise checking on pairs of data points that satisfy the conditions of 1) being ε-close according to adjacency graph 112, and 2) being a part of the simplex of the specific order k.

In one embodiment, the pairwise checking performed by quantum computer 102 can determine which pairs of vertices in simplicial complex 114 are not part of any simplices in simplicial complex 114. Quantum computer 102 can output results of the pairwise checking to classical computer 102, where classical computer 102 can use the pairwise checking results to determine which simplices are absent from simplicial complex 114. Classical computer 102 can determine a difference between the number of absent simplices in simplicial complex 114 and the value 2ⁿ, where this determined difference represents a number of simplices present in simplicial complex 114. The pairwise checking performed by system 100 can be a rejection scheme to filter out simplices that are absent from, or may not be formed in, simplicial complex 114. The number of simplices present in simplicial complex 114 can be used for generating projector P_{Γ} that corresponds to all simplices that are present in simplicial complex 114.

In one embodiment, quantum gates 130 can include gates that form quantum circuit 106 configured to perform the pairwise checking, and quantum gates that form another quantum circuit representing the projector P_{Γ}. Interface 108 can be configured to control quantum circuit 106 based on a command signal received from controller 103. In one embodiment, interface 108 can control quantum circuit 106 by applying quantum gates (e.g., among quantum gates 130) being used for forming quantum circuit 106 on qubits 104. Quantum circuit 106 can be formed using a set of Hadamard gates 132, a set of Toffoli (or C-C-NOT) gates 134, a set of measurement circuits 136, and a set of reset gates 138. Each Hadamard gate among Hadamard gates 132 can act on a single qubit to transform or project the qubit to a superposition quantum state. The set of Toffoli gates 134 can entangle pairs of qubits representing pairs of vertices among simplicial complex 114 with n/2 ancilla qubits that can be among the qubits 104 (the entanglement will be described in more detail below). The n/2 ancilla qubits can store or log whether the pairs of data points undergoing the pairwise checking are ε-close or not (or whether they form 1-simplices or not). The storing or logging using the n/2 ancilla qubits can be outputs of the projector P_{Γ} being implemented by quantum circuit 106 and the outputs can provide a projection or highlight of the simplices that are present in simplicial complex 114 formed from dataset 110. Using n/2 ancilla qubits can allow quantum circuit 106 to process (e.g., check) n/2 pairs of data points at a time (e.g., in one iteration of pairwise checking), such that the pairwise checking can be completed for all

$$( \begin{matrix}n \\ 2\end{matrix} )$$

ε-close pairs of vertices in n−1 iterations of pairwise checking. If n is an odd number, then (n −1)/2 ancilla qubits is used for checking (n−1)/2 pairs at a time, resulting in n iterations of pairwise checking. Measurement circuits 136 can be configured to measure ancilla qubits entangled by the set of Toffoli gates 134, and the measurement results can be provided to interface 108. The set of reset gates 138 can reset the n/2 ancilla qubits to, for example, the |0 [symbol] state, such that the n/2 ancilla qubits can be reused for checking a next iteration of n/2 pairs of data points.

A first iteration of pairwise checking can progress from the set of Hadamard gates 132 to the set of Toffoli gates 134, then to measurement circuits 136, and lastly the reset circuits 138. Iterations subsequent to the first iteration begins at the set of Toffoli gates 134, then progress to measurement circuits 136, and lastly the reset circuits 138. The number of Hadamard gates used for the pairwise checking can be equivalent to the number of data points in dataset 110, which is the same number as the vertices in simplicial complex 114 (e.g., n Hadamard gates). The number of Toffoli gates, the number of measurement circuits 136, and the number of reset gates used for the pairwise checking can be

$$( \begin{matrix}n \\ 2\end{matrix} )$$

since

$$( \begin{matrix}n \\ 2\end{matrix} )$$

pairs of vertices are being checked. Hence, quantum circuit 106 can be a short-depth quantum circuit for complete pairwise testing because it has a relatively short depth of O(n) (e.g., linear depth) and can check all pairs

$$( \begin{matrix}n \\ 2\end{matrix} )$$

pairs of vertices in simplicial complex 114 using n/2 ancilla qubits. For n−1 iterations of pairwise checking, there are n−1 measure-and-reset operations (e.g., implementation of measurement circuits 136 and reset gates 138). Interface 108 can provide the measurement results from measurement circuits 136 to classical computer 102, via controller 103. Classical computer 102 can store the measurement results in

$$( \begin{matrix}n \\ 2\end{matrix} )$$

classical registers 120.

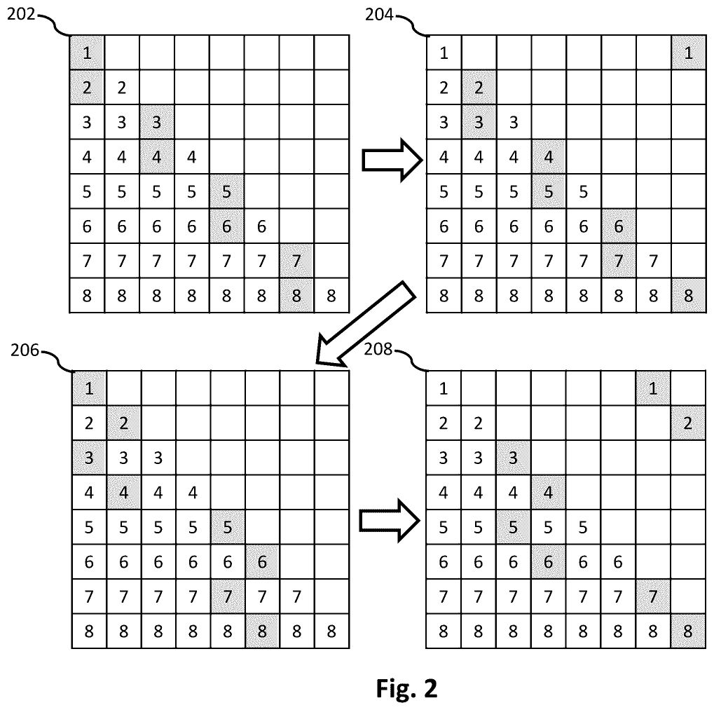

FIG. 2 is a diagram illustrating a cyclic shift technique to select pairs of vertices for different iterations of pairwise testing in one embodiment. In an example shown in FIG. 2, the pairwise testing implemented by system 100 of FIG. 1 can begin at iteration 202, then progress to iteration 204, then iteration 206, then iteration 208, and so on. A set of n/2 pairs of vertices are selected for pairwise testing in each iteration. The selection of pairs of vertices for each iteration can be based on a cyclic shift technique that allows the Toffoli gates 134 (see FIG. 1) to operate in parallel. For example, in iteration 202, the pairs of vertices (1, 2), (3, 4), (5, 6), (7, 8) are being checked. In iteration 204, the pairs of vertices (2, 3), (4, 5), (6, 7), (1, 8) are being checked. In iteration 206, the pairs of vertices (1, 3), (1, 4), (5, 7), (6, 8) are being checked. In iteration 208, the pairs of vertices (3, 5), (4, 6), (1, 7), (2, 8) are being checked. For n=8, a total of 7 iterations (e.g., n−1 iterations) of pairwise checking will be performed using the cyclic shift technique shown in FIG. 2 to check all

$$( \begin{matrix}n \\ 2\end{matrix} )$$

pairs (e.g., 28 pairs for n=8) of vertices.

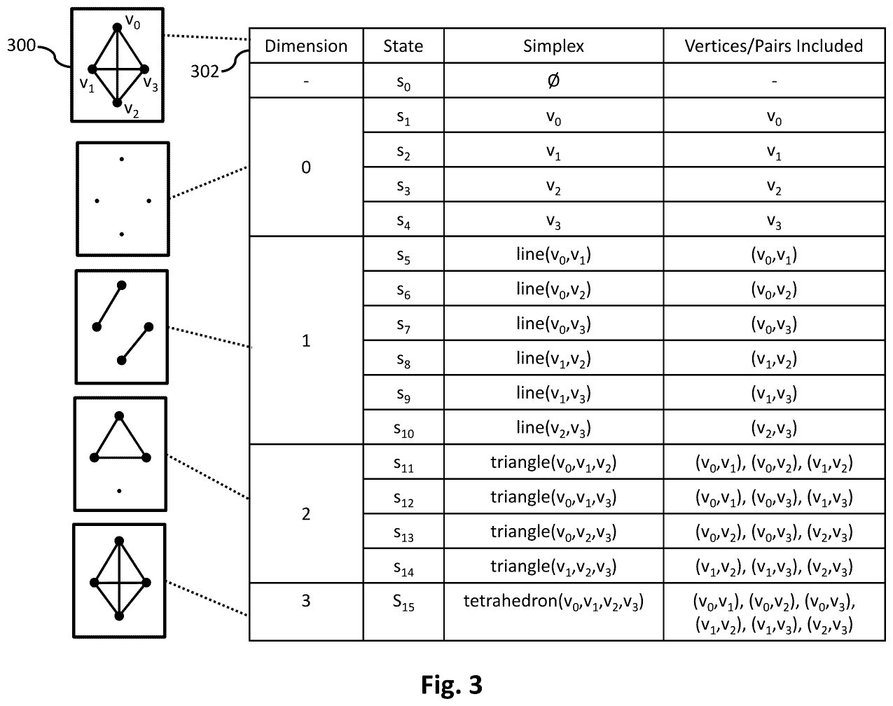

FIG. 3 is a diagram illustrating a plurality of simplices that may be in a simplicial complex in one embodiment. A simplicial complex 300 including four vertices (e.g., n=4) is shown in FIG. 3. Simplicial complex 300 includes vertices v₀, v₁, v₂, v₃ and all vertices are connected to one another (e.g., all pairs are ε-close pairs). As a result of all vertices being connected to one another, simplicial complex 300 includes 2 n simplices, or 16 simplices (e.g., 2⁴=16). Each simplex among simplicial complex 300 can correspond to a simplex of a specific dimension. For example, simplicial complex 300 can include a simplex Ø that has no dimension, four zero-dimension simplices (0-simplices), six one-dimension simplices (1-simplices), four two-dimension simplices (2-simplices), and one three-dimension simplex (3-simplices).

The simplex Ø can be represented as a state s₀. The four 0-simplices are represented as states s₁, s₂, s₃, s₄, where states s₁, s₂, s₃, s₄ include the vertices v₀, v₁, v₂, v₃, respectively. The six 1-simplices are represented as states s₅, s₆, s₇, s₈, s₉, s₁₀, where states s₅, s₆, s₇, s₈, s₉, s₁₀ include the pairs of vertices (v₀, v₁), (v₀, v₂), (v₀, v₃), (v₁, v₂), (v₁, v₃), (v₂, v₃), respectively. The four 2-simplices are represented as states s₁₁, s₁₂, s₁₃, s₁₄, where states s₁₁, s₁₂, s₁₃, include the pairs of vertices (v₀, v₁), (v₀, v₂), (v₁, v₂); (v₀, v₁), (v₀, v₃), (v₁, v₃); (v₀, v₂), (v₁, v₃), (v₂, v₃); and (v₁, v₂), (v₁, v₃), (v₂, v₃), respectively. The one 3-simplex is represented as state s₁₅, where state s₁₅ include the pairs of vertices (v₀, v₁), (v₀, v₂), (v₀, v₃), (v₁, v₂), (v₁, v₃), (v₂, v₃). In one embodiment, if four Hadamard gates (e.g., Hadamard gates 132 in FIG. 1) are used for transforming four qubits representing v₀, v₁, v₂, v₃ in parallel, the output of the four Hadamard gates will be a tensor product representing the sixteen states s₀, . . . , s₁₅.

The simplex with zero dimension or 0-th order (state s₀) and the 0-simplices (states s₁, s₂, s₃, s₄) are considered to be present in the simplicial complex 300 regardless of a result of the pairwise checking being performed by system 100 of FIG. 1. To determine whether the simplices with dimensions greater than or equal to one are present or absent in the simplicial complex 300, system 100 can check all

$$( \begin{matrix}n \\ 2\end{matrix} )$$

pairs of vertices (e.g., six pairs) to determine whether specific pairs of vertices are disconnected (e.g., not ε-close pairs) from one another in simplicial complex 300. The simplices that include the disconnected pairs are vertices that are considered to be absent from simplicial complex 300.

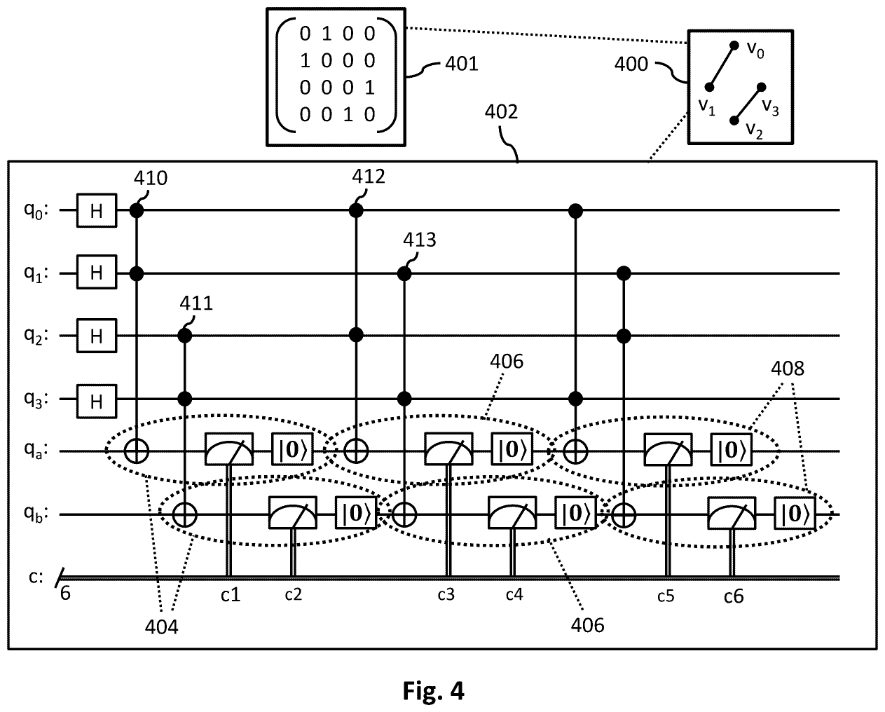

FIG. 4 is a diagram illustrating an example quantum circuit 402 that can be implemented as a quantum circuit for pairwise testing in one embodiment. In an example shown in FIG. 4, a dataset 400 can include data points corresponding to vertices v₀, v₁, v₂, v₃, where the pair of vertices (v₀, v₁) are connected and the pair of vertices (v₂, v₃) are connected. Classical computer 102 shown in FIG. 1 can generate an adjacency graph 401 of dataset 400, and can send adjacency graph 401 to quantum system 101. A quantum circuit 402 can be part of quantum circuit 106 of FIG. 1, and quantum circuit 402 can be implemented to perform pairwise checking on every pair of data points in dataset 400 to identify a specific property of the data points in dataset 400. For example, the specific property can be whether each pair of data points in dataset 400 are within a predefined distance or resolution from one another (e.g., whether each pair is ε-close or not), whether they are close to each other with respect to certain metrics, or whether they belong to same group or class, and/or other properties. In one embodiment, a result of the pairwise checking performed by quantum circuit 402 can indicate a number of disconnected pairs of vertices, and the number of disconnected pairs of vertices can allow classical computer 102 to determine the number of simplices that are absent in simplicial complex 400.

A plurality of qubits, q₀, q₁, q₂, q₃ can represent the vertices v₀, v₁, v₂, v₃. Since dataset 400 includes four data points (e.g., n=4), two ancilla qubits qₐ, q_{b} (e.g., n/2) can be used for the pairwise checking. A plurality of Hadamard gates (e.g., Hadamard gates 132 in FIG. 1) can be used for transforming qubits q₀, q₁, q₂, q₃ into superposition states. In one embodiment, the four Hadamard gates in FIG. 4 can transform qubits q₀, q₁, q₂, q₃ in parallel and the output of the four Hadamard gates will be a tensor product representing sixteen states or sixteen simplices. A set of Toffoli gates (e.g., Toffoli gates 134 in FIG. 1) can entangle pairs of qubits to ancilla qubits qₐ, q_{b}. Measurement of an ancilla qubit entangled to a pair of qubits using a Toffoli gate can indicate whether a pair of vertices represented by the pair of qubits are connected or disconnected. A Toffoli gate is a universal reversible logic gate (e.g., any classical reversible circuit can be constructed from Toffoli gates). Toffoli gates have 3-qubit inputs and outputs, and if the first two qubits are both set to 1, the third qubit will be inverted, otherwise, all qubits remain the same.

In the example shown in FIG. 4, in a first iteration of pairwise checking 404, a Toffoli gate 410 can entangle qubits q₀, q₁ to ancilla qubit qₐ, and Toffoli gate 411 can entangle qubits q₂, q₃ to ancilla qubit q_{b}. Ancilla qubits qₐ, q_{b} can be initialized to the basis state of |0 [symbol] . Since adjacency graph 401 indicates that vertices v₀, v₁ are connected (e.g., element (0, 1) or (1, 0) in adjacency graph 401 being a one), ancilla qubit qₐ will be inverted from |0 [symbol] to |1 [symbol] . A measurement circuit can measure ancilla qubit qₐ, which is state |1 [symbol] , and this result can be written to a classical register c1 of classical computer 102. Similarly, adjacency graph 401 indicates that vertices v₂, v₃ are connected (e.g., element (2, 3) or (3, 2) in adjacency graph 401 being a one), ancilla qubit q_{b} will be inverted from |0 [symbol] to |1 [symbol] . Another measurement circuit can measure ancilla qubit q_{b}, which is state |1 [symbol] , and this result can be written as a classical bit one in a classical register c2 of classical computer 102. A result of the first iteration of pairwise checking 404 shows that the pairs of vertices (v₀, v₁) and (v₂, v₃) are connected pairs. In response to measuring ancilla qubits qₐ, q_{b}, the first iteration of pairwise checking 404 can conclude with reset gates (e.g., reset gates 138 in FIG. 1) resetting ancilla qubits qₐ, q_{b} to state |0 [symbol] , such that ancilla qubits qₐ, q_{b} can be reused for a next iteration of pairwise checking (e.g., a second iteration of pairwise checking 406).

In the second iteration of pairwise checking 406, a Toffoli gate 412 can entangle qubits q₀, q₂ to ancilla qubit qₐ, and a Toffoli gate 413 can entangle qubits q₁, q₃ to ancilla qubit q_{b}. Ancilla qubits qₐ, q_{b} have states |0 [symbol] due to the reset from the first iteration of pairwise checking 404. Since adjacency graph 401 indicates that vertices v₀, v₂ are disconnected (e.g., element (0, 2) or (2, 0) in adjacency graph 401 being a zero), ancilla qubit qₐ will remain |0 [symbol] . A measurement circuit can measure ancilla qubit qₐ, which is state |0 [symbol] , and this result can be written as a classical bit zero in a classical register c3 of classical computer 102. Similarly, adjacency graph 401 indicates that vertices v₁, v₃ are disconnected (e.g., element (1, 3) or (3, 1) in adjacency graph 401 being a zero), ancilla qubit q_{b} will remain |0 [symbol] . A measurement circuit can measure ancilla qubit q_{b}, which is state |0 [symbol] , and this result can be written as a classical bit zero in a classical register c4 of classical computer 102. A result of the second iteration of pairwise checking 406 shows that the pairs of vertices (v₀, v₂) and (v₁, v₃) are disconnected pairs. In response to measuring ancilla qubits qₐ, q_{b}, the second iteration of pairwise checking 406 can conclude with reset gates resetting ancilla qubits qₐ, q_{b} to state |0 [symbol] (even though ancilla bits qₐ, q_{b} are already at state |0 [symbol] ), such that ancilla qubits qₐ, q_{b} can be reused for a next iteration of pairwise checking (e.g., a third iteration of pairwise checking 408).

A result of the third iteration of pairwise checking 408 shows that the pairs of vertices (v₀, v₃) and (v₂, v₃) are disconnected pairs. The result of the third iteration of pairwise checking 408 can be written to classical registers c5 and c6. In response to measuring ancilla qubits qₐ, q_{b}, the third iteration of pairwise checking 408 can conclude with reset gates resetting ancilla qubits qₐ, q_{b} to state |0 [symbol] (even though ancilla bits qₐ, q_{b} are already at state |0 [symbol] ), such that ancilla qubits qₐ, q_{b} can be reused for a next pairwise checking (e.g., for another simplicial complex). The three iterations (e.g., n−1 iterations) conclude the pairwise checking for simplicial complex 400. The result shows that there are four disconnected pairs of vertices in simplicial complex 400 (e.g., four zeroes written to classical register c). The four disconnected pairs of vertices are (v₀, v₂), (v₀, v₃), (v₁, v₂), and (v₁, v₃).

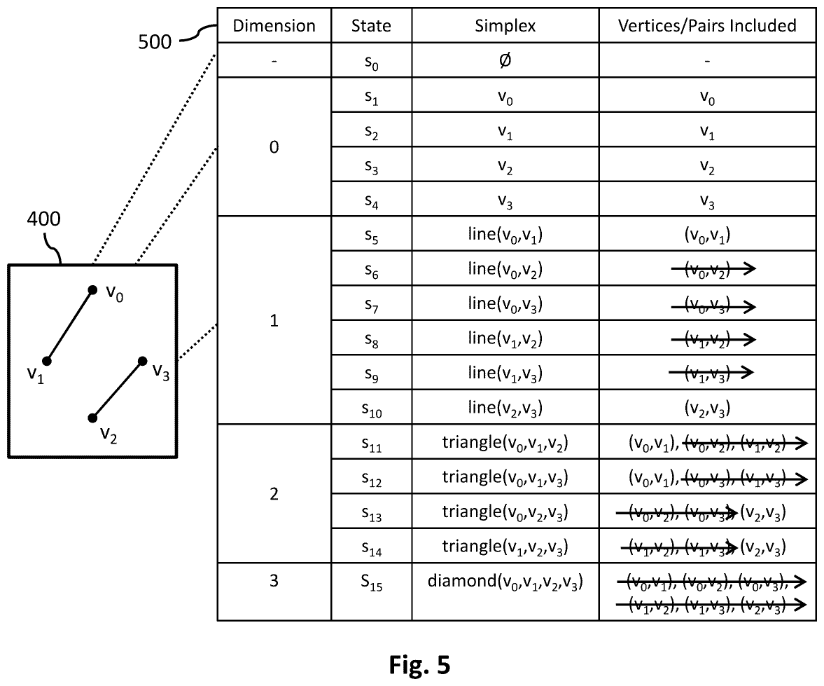

FIG. 5 is a diagram illustrating an example result 500 of an implementation of the quantum circuit 402 shown in FIG. 4 in one embodiment. Result 500 shows four disconnected pairs of vertices (v₀, v₂), (v₀, v₃), (v₁, v₂), and (v₁, v₃). Based on the disconnected pairs of vertices, simplices represented by states s₆, s₇, s₈, s₉, s₁₁, s₁₂, s₁₃, s₁₄, s₁₅, a total of nine simplices are absent from simplicial complex 400. Based on nine simplices being absent from simplicial complex 400, and a maximum number of simplices in simplicial complex is sixteen, classical computer 102 can determine that there are seven simplices in simplicial complex 400.

In one embodiment, classical computer 102 can be configured to tally the number of zeroes written to classical registers c1, c2, c3, c4, c5, c6 (see FIG. 4) to determine the number of disconnected pairs of vertices. Further, based on an order of pairs of vertices being selected by the cyclic shift technique (e.g., see FIG. 2) and an order of states being written to the classical registers, classical computer 102 can determine which pairs of vertices are disconnected pairs. For example, based on the pair of vertices (v₀, v₁) being the first pair being checked, and a state of one being the first state written to classical register c1, classical computer 102 can determine that vertices (v₀, v₁) are connected.

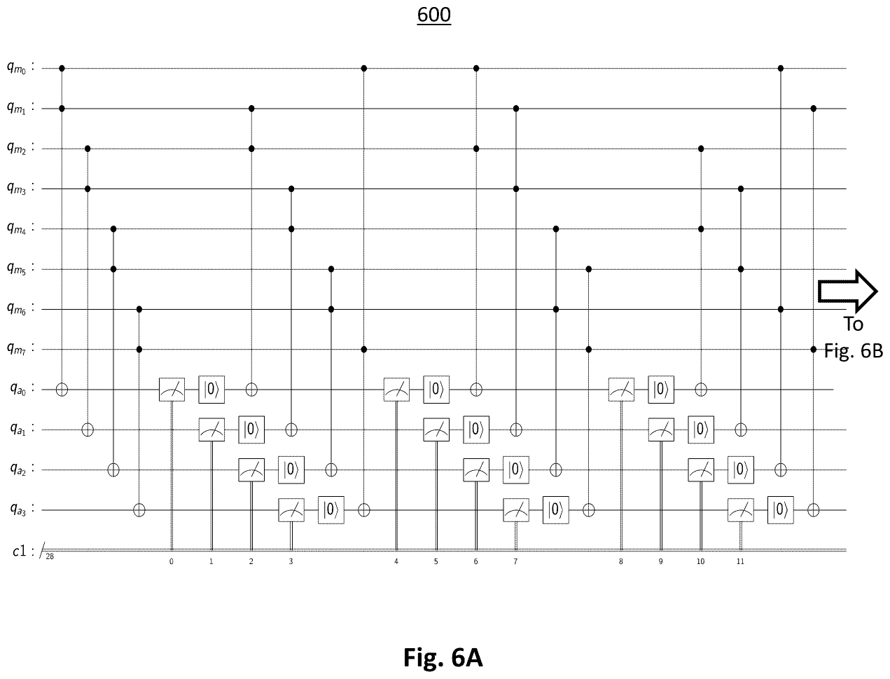

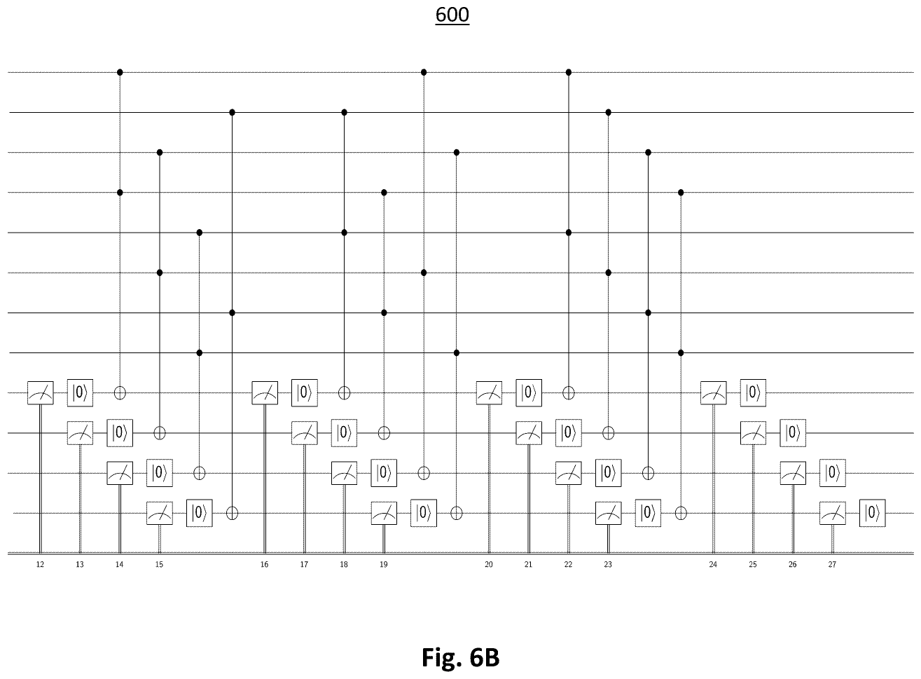

FIG. 6A and FIG. 6B are diagrams illustrating an example quantum circuit 600 that can be implemented as a quantum circuit for pairwise testing in one embodiment. FIG. 6A shows a first portion of quantum circuit 600 and FIG. 6B shows a second portion of quantum circuit 600, where the second portion is a continuation of the first portion. The quantum circuit 600 can be implemented to perform pairwise checking for a simplicial complex that includes eight vertices (e.g., n=8). Quantum circuit 600 can perform seven iterations of pairwise checking, where each iteration utilizes four Toffoli gates, four measurement circuits, and four reset gates are used to check four pairs of vertices. Further, four ancilla qubits are used in quantum circuit 600, and 28 classical registers are used for writing the pairwise checking results.

In an aspect, noisy intermediate-scale quantum (NISQ) processors are quantum processors that include approximately fifty to a few hundred qubits, but may not reach fault-tolerance. NISQ algorithms can be algorithms designed for NISQ processors, and can be hybrid algorithms that use NISQ processors but with reduced calculation load by implementing some parts of the algorithms in classical processors. The pairwise checking described herein need not require quantum random access memory (QRAM) or fault-tolerance quantum computers, and can be NISQ compatible. The number of logic gates implemented for the pairwise checking described herein O(n²ζ̅ₖ) with ζ̅ₖ:=min{1−ζₖ, ζₖ}, and the depth of this circuit is O(n) (e.g. linear) since n/2 of logic gates (e.g., the Toffoli gates) can operate in parallel.

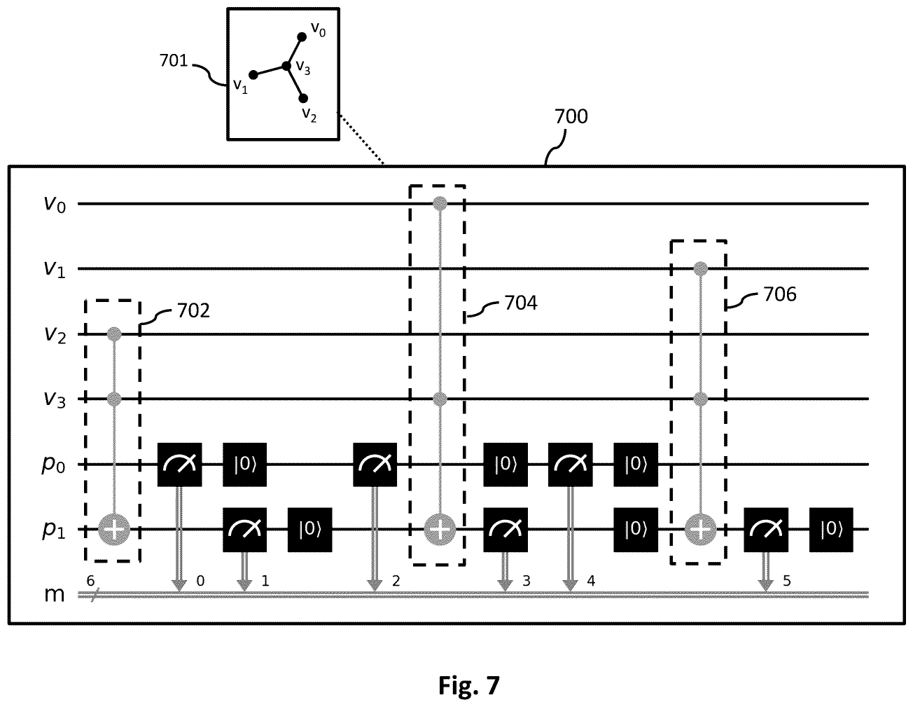

FIG. 7 is a diagram illustrating an example quantum circuit constructed from an implementation as a quantum circuit for pairwise testing in one embodiment. Classical computer 102 can be configured to implement the cyclic shift technique, described with respect to FIG. 2, to program quantum system 101, where programming quantum system 101 includes constructing a new quantum circuit 700. Quantum circuit 700 can be the projector P_{Γ} that project all simplices in a simplicial complex representing a dataset 701. The construction of quantum circuit 700 can include a determination of a number of Toffoli or CCNOT gates to be included in the new quantum circuit. In one embodiment, a result of pairwise checking performed by quantum system 101, described herein can indicate which pairs of data points among dataset 701 are ε-close pairs. Classical computer 102 can use the result indicating the number of ε-close pairs to determine the number of Toffoli gates that can be used for forming quantum circuit 700.

Dataset 701 can include four data points corresponding to four vertices v₀ to v₃ (e.g., n=4). In one embodiment, classical computer 102 can implement the cyclic shift technique based on an adjacency graph of dataset 701 to control quantum computer to perform pairwise checking on every pair of data points in dataset 701. The pairwise checking by quantum system 101 can output a result indicating that the pairs of vertices (v₂, v₃), (v₀, v₃) and (v₁, v₃) are ε-close pairs. In response to the determination that the pairs of vertices (v₂, v₃), (v₀, v₃) and (v₁, v₃) being ε-close, classical computer 102 can program quantum system 101 by constructing quantum circuit 700 with three CCX (C-C-NOT or Toffoli) gates 702, 704, 706. CCX gates 702, 704, 706 can be among the quantum gates 130 shown in FIG. 1. CCX gate 702 can entangle qubits representing vertices (v₂, v₃) with an ancilla qubit p1. CCX gate 704 can entangle qubits representing vertices (v₀, v₃) with ancilla qubit p1. CCX gate 706 can entangle qubits representing vertices (v₁, v₃) with ancilla qubit p1. In one embodiment, CCX gates 702, 704, 706 can be RCCX gates, which is a variation (e.g., a simplified version, or relatively shorter depth) of Toffoli gates. The RCCX gates can have the same functionality as CCX gates—with an exception of all input qubits being in |0 [symbol] state. In one or more embodiment, the methods and systems described herein apply Hadamard gates (e.g., Hadamard gates 132 in FIG. 1, and see FIG. 4) to transform input qubits into mixed states (e.g., superposition of different states). Hence, RCCX gates or CCX gates can be used in the same manner since the mixed states are not all |0 [symbol] .

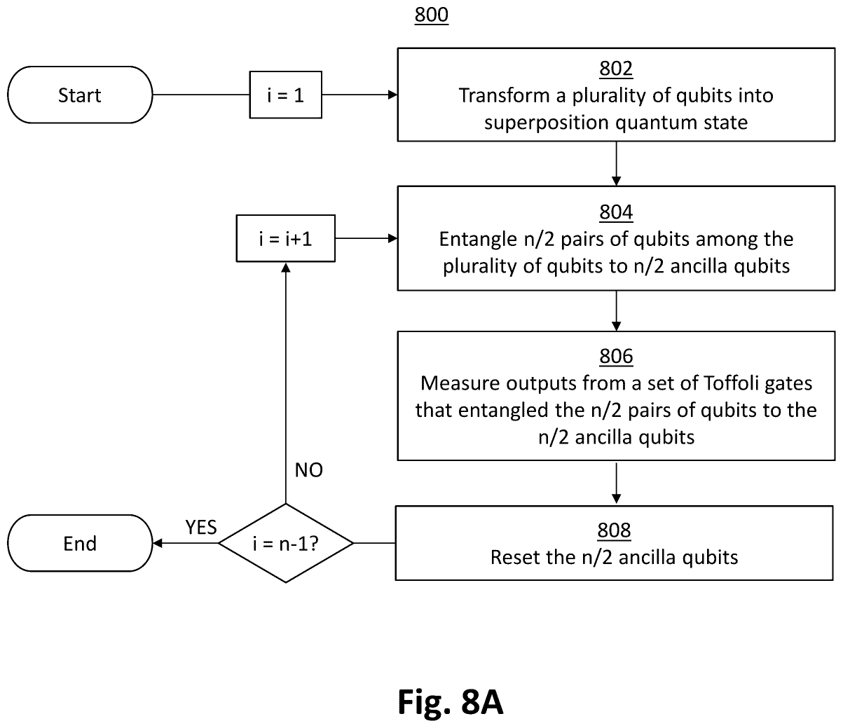

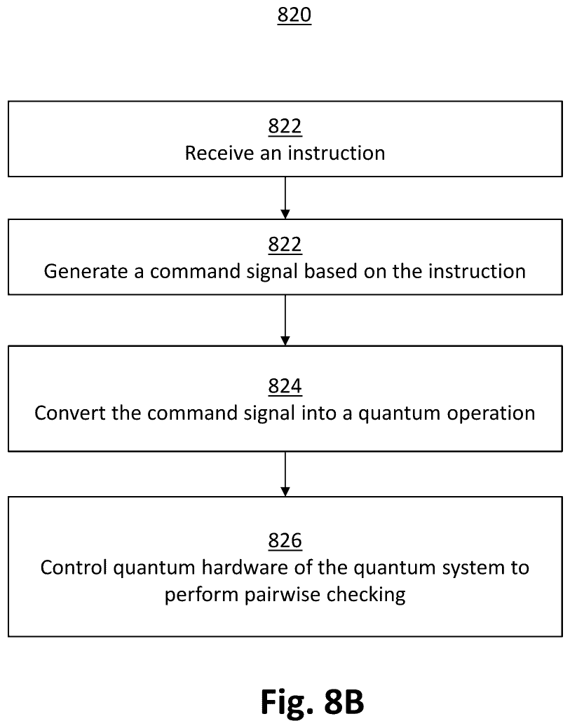

FIG. 8A is a flowchart of an example process 800 that may implement a quantum circuit for pairwise testing according to an embodiment of the disclosure. Example process 800 may include one or more operations, actions, or functions as illustrated by one or more of blocks 802, 804, 806, and/or 808. Although illustrated as discrete blocks, various blocks can be divided into additional blocks, combined into fewer blocks, eliminated, performed in different order, or performed in parallel, depending on the desired implementation.

The process 800 can be implemented to perform pairwise checking of data points in a dataset. Process 800 can begin at block 802. At block 802, an index i can be set to i=1, and a quantum computer can transform a plurality of qubits into superposition quantum state. The plurality of qubits can encode n data points of a dataset. Process 800 can proceed from block 802 to block 804. At block 804, the quantum computer can entangle n/2 pairs of qubits among the plurality of qubits to n/2 ancilla qubits. The n/2 pairs of qubits include distinct pairs of qubits, and one qubit pair is entangled to one ancilla qubit. In one embodiment, the n/2 pairs of qubits being entangled can be selected based on a cyclic shift technique.

Process 800 can proceed from block 804 to block 806. At block 806, the quantum computer can measure outputs from a set of Toffoli gates that entangled the n/2 pairs of qubits to the n/2 ancilla qubits. Process 800 can proceed from block 806 to block 808. At block 808, in response to measuring the outputs from the set of Toffoli gates, the quantum computer can reset the n/2 ancilla qubits. In one embodiment, the measured outputs can indicate a number of pairs of data points in the dataset that are within a predefined resolution from one another. In one embodiment, a topology of the dataset is represented by a simplicial complex, and the measured outputs can indicate a number of simplices that are absent from the simplicial complex. In response to completing block 808, the index i can be incremented by one if i is not equivalent to n−1 and process 800 can return to block 804. Process 800 can end if index i is equivalent to n−1. Hence, blocks 804, 806, 808 can be repeated for n−1 iterations.

FIG. 8B is another flowchart of an example process 820 that may implement a quantum circuit for pairwise testing according to an embodiment of the disclosure. Example process 820 may include one or more operations, actions, or functions as illustrated by one or more of blocks 822, 824, 826, and/or 828. Although illustrated as discrete blocks, various blocks can be divided into additional blocks, combined into fewer blocks, eliminated, performed in different order, or performed in parallel, depending on the desired implementation.

The process 820 can be implemented to perform pairwise checking of data points in a dataset. Process 820 can begin at block 822. At block 822, a controller of a quantum system can receive an instruction. Process 820 can proceed from block 822 to block 824. At block 824, the controller of the quantum system can generate a command signal based on the instruction. Process 820 can proceed from block 824 to block 826. At block 826, an interface of the quantum system can convert the command signal into a quantum operation. Process 820 can proceed from block 826 to block 828. At block 828, the interface of the quantum system can control quantum hardware of the quantum system to perform pairwise checking for every pair of data points in a dataset to identify a property relating to the data points, wherein the data points are represented by the plurality of qubits.

FIG. 9 illustrates a schematic of an example computer or processing system 11 that may implement a quantum circuit for pairwise testing in one embodiment of the present disclosure. The computer system 11 is an example of a suitable processing system and is not intended to suggest any limitation as to the scope of use or functionality of embodiments of the methodology described herein. The computer system 11 shown may be operational with numerous other general-purpose or special purpose computing system environments or configurations. Examples of well-known computing systems, environments, and/or configurations that may be suitable for use with the processing system shown in FIG. 9 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, supercomputers, quantum computing systems, hybrid systems including quantum computers and classical computers, and distributed cloud computing environments that include any of the above systems or devices, and the like. Classical computers among computer system 11 can execute classical computing processes by performing operations based on information encoded in bits. Quantum computers among computer system 11 can execute quantum computing processes by performing operations based on information encoded in qubits.

The computer system 11 may be described in the general context of computer system executable instructions, such as program modules, being implemented by a computer system. Generally, program modules may include routines, programs, objects, components, logic, data structures, and so on that perform particular tasks or implement particular abstract data types. The computer system 11 may be practiced in distributed cloud computing environments where tasks are performed by remote processing devices that are linked through a communications network. In a distributed cloud computing environment, program modules may be located in both local and remote computer system storage media including memory storage devices.

The components of computer system 11 may include, but are not limited to, one or more processors or processing units 12, a system memory 16, a bus 14, storage system(s) 18, I/O interface(s) 20, network adapter(s) 22, network 24, devices 26, and display(s) 28. Bus 14 may couple various components of computer system 10. The processor 12 may include modules (e.g., programming modules) that performs the methods described herein. The modules among processor 12 may be programmed into the integrated circuits of the processor 12, or loaded from memory 16, storage device 18, or network 24 or combinations thereof. Processor 12 can be, for example, a microprocessor, a microcontroller, a processor core, a multicore processor, central processing unit (CPU) of computing devices such as a classical computer and/or quantum computers, and/or other types of computer processing element.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Universal Serial Bus (USB), Video Electronics Standards Association (VESA) local bus, and Peripheral Component Interconnects (PCI) bus.

Computer system 11 may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. Computer system may further include other removable/non-removable, volatile/non-volatile computer system storage media. By way of example, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

Computer system 11 may also communicate with one or more external devices 26 such as a keyboard, a pointing device, a display 28, network card, modem, etc. that enable a user to interact with computer system and/or that enable computer system 11 to communicate with one or more other computing devices. Devices 26 can be connected to components among computer system 11 via bus 14 and/or input/output (I/O) interfaces 20.

Computer system 11 can communicate with one or more networks 24 such as a local area network (LAN), a general wide area network (WAN), and/or a public network (e.g., the Internet) via network adapter 22 and/or I/O interfaces 20. Computer system 11 can communicate with networks 24 through wired connections (e.g., wires or cables connected to bus 14) or wireless connections (e.g., through network cards among I/O devices 20 and/or network adapter 22). Network adapter 22 can communicate with the other components of computer system 11 via bus 14. It should be understood that although not shown, other hardware and/or software components could be used in conjunction with computer system 10. Examples include, but are not limited to: field-programmable gate array (FPGA), system on chip (SoC), microcode, device drivers, redundant processing units, external disk drive arrays, RAID systems, tape drives, and data archival storage systems, etc.

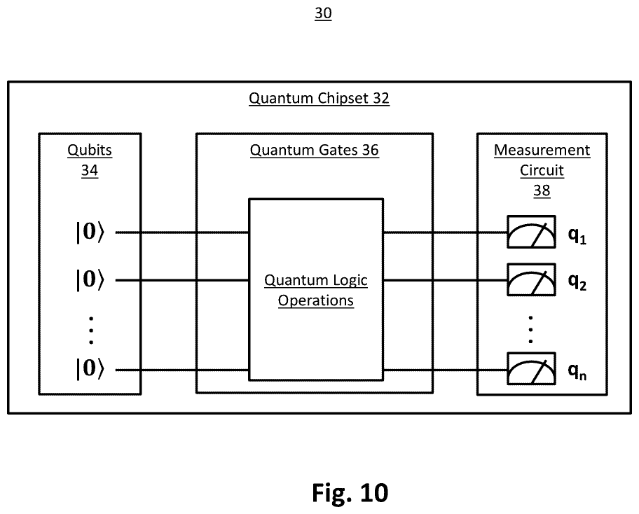

FIG. 10 illustrates a schematic of an example quantum computing system 30 that may implement a quantum circuit for pairwise testing in one embodiment of the present disclosure. Quantum computing system 30 can be implemented by a quantum computer among processor 12 shown in FIG. 9, or coupled to network 24 shown in FIG. 9). Quantum computing system 30 can include a quantum chipset 32. Quantum chipset 32 can include one or more components configured to operate on a plurality of qubits 34. In an aspect, qubits 34 can be arranged in a two-dimensional or three-dimensional array, such as being arranged in a lattice structure. A two-dimensional qubit array can be formed on a surface of a two-dimensional wafer, and the qubits 34 can be arranged in a two-dimensional lattice structure and configured to communicate with one another. A three-dimensional device array can be formed by a stack of two-dimensional wafers, and qubits 34 can be arranged in a three-dimensional lattice structure and configured to communicate with one another via connections between the two-dimensional wafers.

Quantum chipset 32 can be a quantum computing core surrounded by an infrastructure to shield quantum chipset 32 from sources of electromagnetic noise, mechanical vibration, heat, and other sources of noise, which tend to degrade performance. Magnetic shielding can be used to shield the system components from stray magnetic fields, optical shielding can be used to shield the system components from optical noise, thermal shielding and cryogenic equipment can be used to maintain the system components at controlled temperature, etc. For example, an infrastructure that can surround quantum chipset 32 can be a refrigerator that can cool the quantum chipset to an operating temperature of quantum chipset 32.

The plurality of qubits 34 can be denoted as q₁, q₂, . . . , qₙ. Quantum chipset 32 can operate by performing quantum logic operations (e.g., using quantum gates 36) on qubits 34. Quantum gates 36 can include one or more single-qubit gates and/or two-qubit gates. Quantum circuits can be formed based on quantum gates 36, and quantum chipset 32 can operate the quantum circuits to perform quantum logic operations on single qubits or conditional quantum logic operations on multiple qubits. Conditional quantum logic can be performed in a manner that entangles the qubits. Control signals can be received by quantum chipset 32, and quantum chipset 32 can use the received control signals to manipulate the quantum states of individual qubits and the joint states of multiple qubits.

Measurement circuit 38 can include circuit components configured to measure a basis of qubits 34, where the basis is a measurement that will yield a classical bit result. Each measurement performed by measurement circuit 38 can be read out to a device (e.g., a classical computer) connected to quantum computing system 30. A plurality of measurement results provided by measurement circuit 38 can result in a probabilistic outcome.

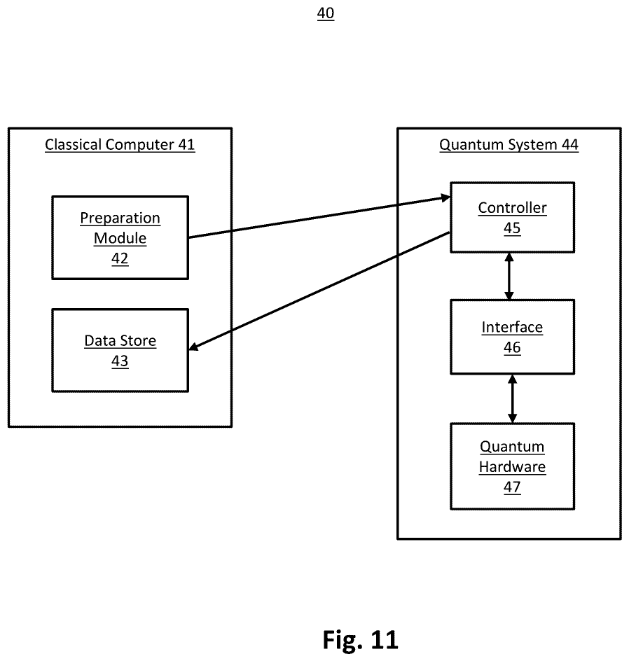

FIG. 11 illustrates a block diagram of an example system 40 that can facilitate execution of a quantum algorithm. As shown, a classical computer 41 can be electronically integrated, via any suitable wired and/or wireless electronic connection, with a quantum system 44. The quantum system 44 can be any suitable set of components capable of performing quantum operations on a physical system. In the example embodiment depicted in FIG. 11, quantum system 44 can include controller 45 (e.g., a local classical controller), an interface 46 (e.g., a classical-quantum interface), and quantum hardware 47. In some embodiments, all or part of each of the controller 45, the interface 46, and quantum hardware 47 may be located in a cryogenic environment to aid in the performance of the quantum operations.

Controller 45 may be any combination of digital computing devices capable of performing a quantum computation, such as executing a quantum circuit, in combination with interface 46. Such digital computing devices may include digital processors and memory for storing and executing quantum commands using interface 46. Additionally, such digital computing devices may include devices having communication protocols for receiving such commands and sending results of the performed quantum computations to classical computer 41. Additionally, the digital computing devices may include communications interfaces with the interface 46. Controller 45 can be configured to receive classical instructions (e.g., from classical computer 41) and convert the classical instructions into drive signals. The drive signals can be used for driving or manipulating qubits and/or quantum gates and/or circuits among quantum hardware 47.

Interface 46 may be a combination of devices capable of receiving command signals from controller 45 and converting those signals into quantum operations for execution on the quantum hardware 47. Additionally, interface 46 may be capable of converting signals received from the quantum hardware 47 into digital signals capable of processing and transmitting by controller 45. Devices included in interface 46 may include, but are not limited to, digital-to-analog converters, analog-to-digital converters, waveform generators, attenuators, amplifiers, optical fibers, lasers, and filters.

Quantum hardware 47 may be any hardware capable of using quantum states to process information. Such hardware may include a collection of qubits, and mechanisms to couple/entangle such qubits, in order to process information using said quantum states. Such qubits may include, but are not limited to, charge qubits, flux qubits, phase qubits, spin qubits, and trapped ion qubits.

The classical computer 41 can be any suitable combination of computer-executable hardware and/or computer-executable software capable of executing a preparation module 42 to perform quantum computations with data contained in a data store 43 as part of building and implementing a machine learning protocol. Data store 43 may be a repository for data to be analyzed using a quantum computing algorithm, as well as the results of such analysis. In an example system, classical computer 41 can be a laptop computer, a desktop computer, a vehicle-integrated computer, a smart mobile device, a tablet device, and/or any other suitable classical computing device. Additionally or alternatively, classical computer 41 may also operate as part of a cloud computing service model, such as Software as a Service (SaaS), Platform as a Service (PaaS), or Infrastructure as a Service (IaaS). Classical computer 102 may also be located in a cloud computing deployment model, such as a private cloud, community cloud, public cloud, or hybrid cloud. Aspects of this embodiment are described in more detail below with reference to FIG. 12 and FIG. 13.

Preparation module 42 may be a program or module capable of preparing classical data from data store 43 to be analyzed as part of the implementation of a quantum circuit. Preparation module 42 may be instantiated as part of a larger algorithm, such as a function call of an application programming interface (API) or by parsing a hybrid classical-quantum computation into aspects for quantum and classical calculation. Preparation module 42 may generate instructions for creating a quantum circuit using quantum gates in quantum hardware 47. In an embodiment, such instructions may be stored by controller 41, and may instantiate the execution of the components of interface 46 so that the quantum operations of the quantum gates may be performed on quantum hardware 47.

FIG. 12 depicts a cloud computing environment according to an embodiment of the present invention. It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

Referring now to FIG. 12, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 12 are intended to be illustrative only and that computing nodes 10 and cloud computing environment 50 can communicate with any type of computerized device over any type of network and/or network addressable connection (e.g., using a web browser).

FIG. 13 depicts abstraction model layers according to an embodiment of the present invention. Referring now to FIG. 13, a set of functional abstraction layers provided by cloud computing environment 50 (FIG. 12) is shown. It should be understood in advance that the components, layers, and functions shown in FIG. 13 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and pairwise checking 96.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more instructions for implementing the specified logical function(s). In some alternative implementations, the functions noted in the blocks may occur out of the order noted in the Figures. For example, two blocks shown in succession may, in fact, be performed substantially concurrently, or the blocks may sometimes be performed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus comprising:
a controller configured to generate a command signal;
quantum hardware including a plurality of qubits; and
an interface connected to the controller and the quantum hardware, the interface being configured to control the quantum hardware based on the command signal received from the controller to perform pairwise checking for every pair of data points in a dataset to identify a property relating to the data points, wherein the data points are represented by the plurality of qubits.

2. The apparatus of claim 1, wherein:
the dataset comprises n data points;
the quantum hardware is configured to:
perform n−1 iterations of pairwise checking; and
perform pairwise checking on n/2 pairs of data points in each iteration of pairwise checking.

3. The apparatus of claim 2, wherein for each iteration of pairwise checking, the n/2 pairs of data points that undergo the pairwise checking is selected using a cyclic shift technique, and the n/2 pairs of data points are checked in parallel.

4. The apparatus of claim 1, wherein the property relates to a pair of data points within a predefined resolution from one another, and the result of the pairwise checking indicates a number of pairs of data points that are within the predefined resolution from one another.

5. The apparatus of claim 1, wherein a topology of the dataset is represented by a simplicial complex, and the result of the pairwise checking indicates a number of simplices that are absent from the simplicial complex.

6. The apparatus of claim 1, wherein the quantum hardware comprises:
a set of Hadamard gates configured to transform the plurality of qubits into superposition quantum state, wherein the plurality of qubits encodes the data points of the dataset;
a set of Toffoli gates configured to entangle the plurality of qubits to a set of ancilla qubits, wherein one pair of qubits is entangled to one ancilla qubit;
a set of measurement circuits configured to measure outputs from the set of Toffoli gates; and
a set of reset gates configured to reset the set of ancilla qubits.

7. The apparatus of claim 6, wherein:
the dataset comprises n data points;
the pairwise checking includes n −1 iterations of pairwise checking; and
for each iteration of pairwise checking, the set of Toffoli gates entangle n/2 pairs of data points to n/2 ancilla qubits.

8. The apparatus of claim 7, wherein in response to the set of reset gates resetting the set of ancilla qubits, the n/2 pairs of qubits entangled to the n/2 ancilla qubits are replaced by a new set of n/2 qubits among the plurality of qubits, and the set of Toffoli gates are configured to entangle the new set of n/2 qubits to the n/2 ancilla qubits.

9. The apparatus of claim 6, wherein the set of Toffoli gates are a set of RCCX gates.

10. A system comprising:
a first computing device configured to process data encoded in binary data;
a second computing device configured to be in communication with the first computing device, the second computing device being configured to process data encoded in qubits, wherein the second computing device comprises:
a controller configured to at least:
receive an instruction from the first computing device; and
generate a command signal based on the instruction;
quantum hardware including a plurality of qubits; and
an interface connected to the controller and the quantum hardware, the interface being configured to control the quantum hardware based on the command signal received from the controller to perform pairwise checking for every pair of data points in a dataset to identify a property relating to the data points, wherein the data points are represented by the plurality of qubits.

11. The system of claim 10, wherein the property relates to a pair of data points within a predefined resolution from one another, and the result of the pairwise checking indicates a number of pairs of data points that are within the predefined resolution from one another.

12. The system of claim 10, wherein a topology of the dataset is represented by a simplicial complex, and the first computing device is configured to:
receive a result of the pairwise checking from the second computing device; and
use the result to determine a number of simplices that are absent from the simplicial complex.

13. The system of claim 12, wherein the first computing device is further configured to use the result to construct a projector that projects to all simplices that are in the simplicial complex.

14. The system of claim 12, wherein the projector is a quantum circuit comprising a number of Toffoli gates, and the number of Toffoli gates is equivalent to a number of pairs of data points that are within a predefined resolution from one another in the dataset.

15. The system of claim 10, wherein the first computing device is configured to:
generate an adjacency graph of the simplicial complex; and
send the adjacency graph to the second computing device, wherein the pairwise checking performed by the second computing device is based on the adjacency graph.

16. The system of claim 10, wherein:
the dataset comprises n data points;
the second computing device is configured to:
perform n −1 iterations of pairwise checking; and
perform pairwise checking on n/2 pairs of data points in each iteration of pairwise checking

17. The system of claim 15, wherein for each iteration of pairwise checking, the n/2 pairs of data points that undergo the pairwise checking is selected using a cyclic shift technique, and the n/2 pairs of data points are checked in parallel.

18. The system of claim 10, wherein the second quantum computing device comprises:
a set of Hadamard gates configured to transform a plurality of qubits into superposition quantum state, wherein the plurality of qubits encodes the data points of the dataset;
a set of Toffoli gates configured to entangle the plurality of qubits to a set of ancilla qubits, wherein one pair of qubits is entangled to one ancilla qubit;
a set of measurement circuits configured to measure outputs from the set of Toffoli gates; and
a set of reset gates configured to reset the set of ancilla qubits.

19. The system of claim 18, wherein:
the dataset comprises n data points;
the pairwise checking includes n −1 iterations of pairwise checking; and
for each iteration of pairwise checking, the set of Toffoli gates entangle n/2 pairs of data points to n/2 ancilla qubits.

20. The system of claim 18, wherein in response to the set of reset gates resetting the set of ancilla qubits, the n/2 pairs of qubits entangled to the n/2 ancilla qubits are replaced by a new set of n/2 qubits among the plurality of qubits, and the set of Toffoli gates are configured to entangle the new set of n/2 qubits to the n/2 ancilla qubits.

21. The system of claim 18, wherein the set of Toffoli gates are RCCX gates.

22. A method of operating a quantum system, the method comprising:
receiving, by a controller of a quantum system, an instruction;
generating, by the controller of the quantum system, a command signal based on the instruction;
converting, by an interface of the quantum system, the command signal into a quantum operation; and
based on the quantum operation, controlling, by the interface of the quantum system, quantum hardware of the quantum system to perform pairwise checking for every pair of data points in a dataset to identify a property relating to the data points, wherein the data points are represented by the plurality of qubits.

23. The method of claim 22, wherein the pairwise checking comprises:
transforming the plurality of qubits into superposition quantum state, wherein the plurality of qubits encodes n data points of the dataset;
entangling n/2 pairs of qubits among the plurality of qubits to n/2 ancilla qubits, wherein the n/2 pairs of qubits include distinct pairs of qubits, and one qubit pair is entangled to one ancilla qubit;
measuring outputs from a set of Toffoli gates that entangled the n/2 pairs of qubits to the n/2 ancilla qubits; and
in response to measuring the outputs from the set of Toffoli gates, resetting the n/2 ancilla qubits,
wherein the entangling, the measuring, and the resetting is repeated for n −1 iterations.

24. The method of claim 22, further comprising selecting the n/2 pairs for entangling using a cyclic shift technique.

25. The method of claim 22, wherein the measured outputs indicate a number of pairs of data points in the dataset that are within a predefined resolution from one another.
